(19) United States
(12) Patent Application Publication
(10) Pub. No.: US 2019/0360650 A1
(43) Pub. Date: Nov. 28, 2019

(54) LIGHTING UNIT

(71) Applicant: Gary Toner, Lancaster, NY (US)

(72) Inventor: Gary Toner, Lancaster, NY (US)

(21) Appl. No.: 16/421,569

(22) Filed: May 24, 2019

Related U.S. Application Data
(63) Continuation of application No. 62/676,385, filed on May 25, 2018.
(60) Provisional application No. 62/688,840, filed on Jun. 22, 2018.

(51) Int. Cl. F21S 9/03; H01L 31/048; F21V 23/02

(52) U.S. Cl. CPC F21S 9/037; F21V 23/023; H01L 31/048

(57) ABSTRACT

There is a lighting unit having a housing having a base portion that has a surrounding wall. The housing has a solar panel support portion that is supported on the base portion. A solar panel is mounted on the solar panel support portion and energy gathered by the solar panel is stored in a rechargeable battery. The base portion has a base wall and a surrounding wall, and the surrounding wall may have a cylindrical shape, a conical shape, or an inverted conical shape. Surface mounted lights may be mounted on any surface of the lighting unit and can be in any shape or pattern. A base recess may be formed in the base wall and supports a recessed LED. A recess wall may be formed in the surrounding wall and supports a recessed LED. The surface mounted and recessed LEDs are for illuminating a flag or flagpole finial.

### CROSS REFERENCE TO RELATED APPLICATIONS

This application claims the benefit of U.S. Provisional Patent Application No. 62/676,385 filed on May 25, 2018, and this application claims the benefit of U.S. Provisional Patent Application No. 62/688,840 filed on Jun. 22, 2018 and the entire contents and disclosures of each are hereby incorporated herein by reference.

### BACKGROUND

### Background of Invention

People enjoy displaying flags in their yards and at their businesses. The flags may be the U.S. flag, the flags of other nations, or flags that display business names or logos. However, as night falls there is no source of light to illuminate the flags so that they can be seen.

There are methods for lighting flags at night, for example ground lights that emit beams of light in a direction toward the flag. However, the owner often has to provide lights and attach them to a suitable support, and then hardwire the lights to the power grid. This becomes costly over time and the many owners of such lights simple stop using them to save money. There are also lighting devices are that powered with solar power, but to date such lighting devices are ineffective at beaming the light to where it is needed. For example, such existing solar lights will send a beam of light directly down the flagpole and will illuminate a portion of the flag and in some instances almost none of the flag depending how the wind is blowing the flag. These lights are simply incapable of illuminating the flag if there is wind or a breeze and the flag is waving in the wind. Thus, these devices fail to illuminate the most beautiful aspects of a flag, namely when it is waving in the wind at night.

What is needed is an improved lighting device that can be mounted on flagpole or virtually any post that is capable of illuminating the flag or post at all times, that is, when the flag is still and not moving and when it is being moved by the wind. The lighting device needs to be easy to manufacture, inexpensive, easy install and have a long working life.

### SUMMARY

A lighting unit is provided that has a housing, and the housing includes a base portion and a solar panel support portion. The base portion and solar panel support portion are connected with, for example, fasteners or adhesives or both and define a housing interior, and the solar panel support portion has a circular shape in one of the embodiments and in other embodiments could be differently shaped. The lighting unit also has solar panels that are supported on the solar panel support portion. The solar panel support portion has a finial receiving extension that extends through the housing interior. The finial receiving extension defines a finial receiving interior that is sized such that a support shaft of a flagpole finial can be passed through the finial receiving extension. This allows the lighting unit to be mounted on a flagpole or, for example, a post.

The lighting unit also includes a rechargeable battery along with associated circuitry, wiring and recessed and surface mounted light emitting diodes (hereinafter referred to as LEDs herein) that are disposed in the housing interior defined in the housing, but the LEDs are exposed so as to be visible when energized. Solar energy is stored in the rechargeable battery and then emitted when it is dark by the recessed and surface mounted LEDs or light bulbs. The solar light circuitry controls the process of using the energy gathered by the solar panels and stored in the rechargeable battery to power the recessed and surface mounted LEDs when it is dark or during low light situations.

The base portion of the housing has a surrounding wall, and the base portion of the housing has a base wall from which the surrounding wall extends. The surrounding wall may be in the form of a conical shaped wall, an inverted conical shaped wall or a cylindrical shaped wall, or may have other shapes in other embodiments. The base wall meets with the surrounding wall.

The diameter of the base wall is less than the diameter of the solar panel support portion in one embodiment, or has the same diameter as the solar panel support portion in one embodiment, or has a greater diameter than the solar panel support portion in another embodiment. The surrounding wall and the base wall are formed as a one-piece body in one of the embodiments, such that the base portion is a one-piece body. The base wall has base recess walls that define base recesses and recessed LEDs are disposed in base recesses. In the conical shaped wall embodiment there are recess walls that define recesses and recessed LEDs are disposed in the recesses.

In other embodiments the surrounding wall may have any desired shape or geometry for use in different applications, for example it may be rectangular shaped, triangular shaped, oval shaped, and the base wall and the solar panel support portion would have a like geometry.

Surface mounted LEDs are also supported on the solar panel support portion, the surrounding wall, and the base wall in some of the embodiments alone, or in combinations with the recessed LEDs mentioned above.

The recessed and surface mounted LEDs may be arranged in virtually any pattern, or in rows, or annularly spaced from another, or randomly spaced from one another, and in some embodiments there are no LEDs supported on the surrounding wall, the conical shaped wall, or the inverted conical shaped wall, or the cylindrical shaped wall. Light is emitted from the recessed and surface mounted LEDs such that the flag is illuminated by them when there is no breeze, and when there is a breeze. Thus, the user or an observer can see the illuminated flag at all times, regardless of whether there is or is not a breeze, and can see the flagpole finial at all times. In addition, the finial is always illuminated by the surface mounted LEDs that are supported on the solar panel support portion.

### BRIEF DESCRIPTION OF THE DRAWING FIGURES

FIG. 1 is front view of a lighting unit having a conical shaped wall that extends from a base wall to a solar panel support portion.

FIG. 1A is a top view of the lighting unit wherein the interior of the lighting unit is shown and the solar panel support portion is absent.

FIG. 2 is a top view of the lighting unit.

FIG. 3 is a bottom view of another embodiment of the lighting unit having additional base recess walls and recessed light emitting diodes supported by the base recess walls, and showing additional recess walls and recessed light emitting diodes supported by the recess walls.

FIG. 4 is a perspective view of the lighting unit mounted on flagpole illuminating a flag.

FIG. 4A is a front view of a flagpole finial.

FIG. 4B is a front view of the lighting unit supported on a flagpole.

FIG. 5 is a top view of another embodiment of the solar panels of the lighting unit.

FIG. 5a is a top view of a ring shaped solar panel.

FIG. 6 is a bottom perspective view of the lighting unit.

FIG. 6A is a bottom perspective view of a light lighting unit having surface mounted lights.

FIG. 6B is a bottom view of another embodiment of the light lighting unit.

FIG. 7 is a side view of the lighting unit wherein the conical shaped wall is replaced with a cylindrical shaped wall.

FIG. 8 is a top view of the lighting unit that shows the solar panel support portion supporting solar panels and at least one surface mounted LED.

FIG. 9 is a side view wherein the conical shaped wall is replaced with an inverted conical shaped cylindrical wall.

### DESCRIPTION

As used in this description, like surfaces, features, components, parts and structures use like reference numerals. In addition, as used in the description the phrase light emitting diodes (LEDs) is used, but the application and the claims recited herein are not limited to just LEDs. Rather, conventional light bulbs could be used and any light bulb developed in the future could be used.

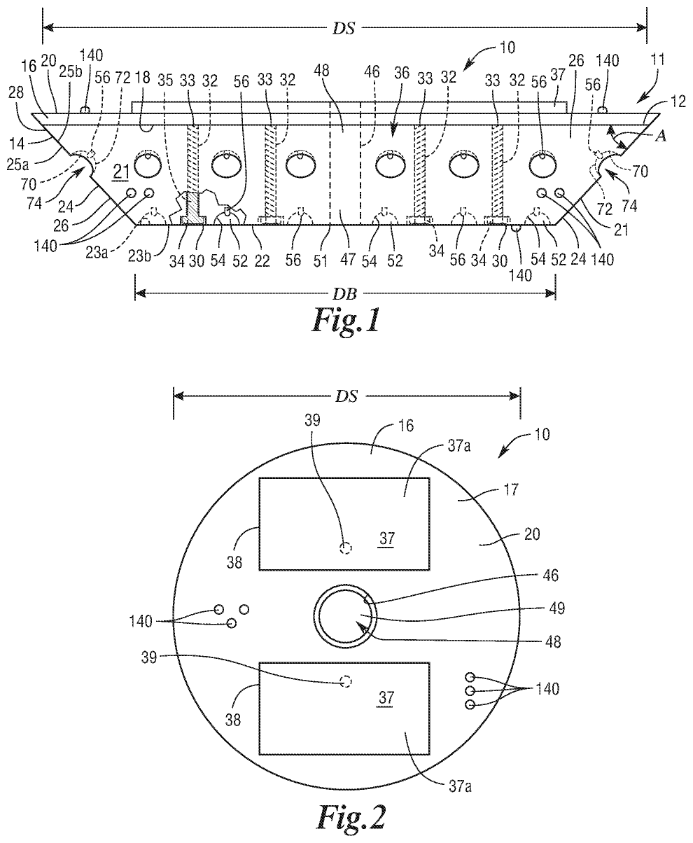

As shown in FIG. 1 there is a lighting unit 10 that has a housing 12. The housing has a base portion 14, and the housing 12 has a solar panel support portion 16 that is supported on the base portion 14.

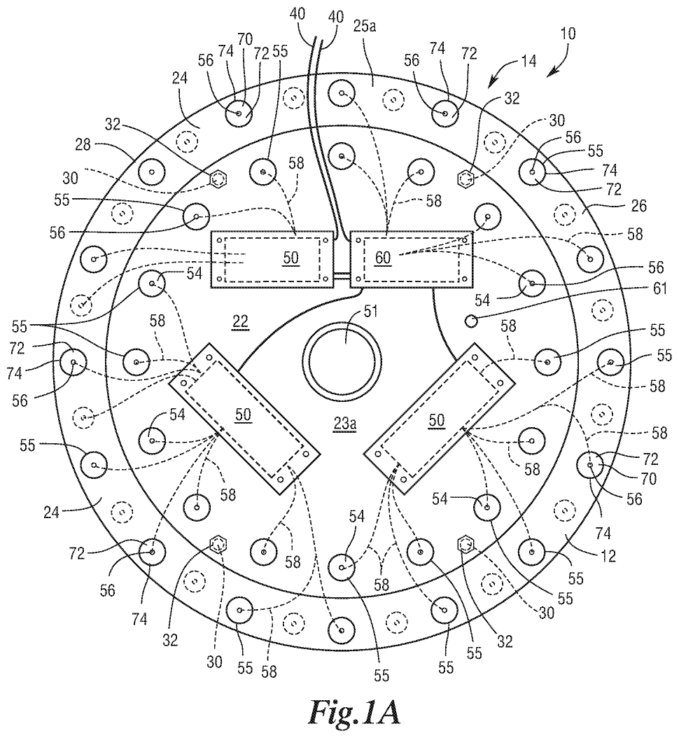

As shown in FIGS. 1 and 2, the solar panel support portion 16 is has a circular shape 17 in one of the embodiments and may be flat. The solar panel support portion 16 has opposed interior and exterior solar panel surfaces 18, 20 and is made of plastic, and may be made of metal and other suitable materials in other embodiments. The solar panel support portion 16 has a diameter designated DS in FIG. 2, and DS is ten to twelve inches. In other embodiments DS may be less than ten inches in diameter or more than twelve inches in diameter.

The base portion 14 of the housing 12 has a base wall 22 that may have a circular shape and has interior and exterior base wall surfaces 23a, 23b. The base portion 14 also has a surrounding wall 21 that is embodied as a conical shaped wall 24 in one embodiment, and the conical shaped wall 24 extends from the base wall 22. The conical shaped wall 24 has interior and exterior conical wall surfaces 25a, 25b. The base wall 22 and the conical shaped wall 24 are formed as a one-piece body 26 and are plastic in one embodiment, but may be may be made of metal or other materials in other embodiments, or they may be made separately and held together with, for example adhesives in other embodiments. It is pointed out that the conical shaped wall 24 abuts against the solar panel support portion 16 such that the solar panel support portion 16 is supported on the base portion 14.

The conical shaped wall 24 extends from the base wall 22 to a conical shaped wall edge 28 and flares outwardly as it extends from the base wall 22 to the solar panel support portion 16. It is pointed out that the diameter of the conical shaped wall 24 as measured at the conical shaped wall edge 28 is the same or substantially the same as the diameter of designated DS of the solar panel support portion 16 shown in FIG. 2. Thus, when the solar panel support portion 16 is mounted or supported on the conical shaped wall 24 the solar panel support portion 16 and the conical shaped wall 24 are flush or substantially flush with one another. It is further pointed out that the diameter of the conical shaped wall 24 as measured at the conical shaped wall edge 28 is greater than the diameter of the base wall 22 designated DB in FIG. 1. Thus, the conical shaped wall 24 tapers inwardly as it extends from the conical shaped edge wall 28 to the base wall 22. In other words, the diameter of the conical shaped wall 24 decreases as it extends from the conical shaped wall edge 28 to the base wall 22.

FIG. 1A is a top view of the base portion 14 wherein the solar panel support portion 16 is not present. The base wall 22 defines fastener openings 30 (FIG. 1), and internally threaded bores 33 (FIG. 1) extend from the interior surface 18 of solar panel support portion 16 into the solar panel support portion 16. Fasteners 32 having threaded portions 35 are provided. The threaded portions 35 extend through the fastener openings defined in the base wall 22 and the heads 34 of the fasteners 32 abut against the base wall 22. The treaded portion 35 are threaded to the internally threaded bores 33 formed in the solar panel portion 16 thus connecting the base portion 14 and solar panel portion 16. When so connected, the conical shaped wall edge 28 abuts against the solar panel portion 16, and the solar panel support portion 16 and the base portion 14 are held together. When the solar panel support portion 16 is so mounted on the base portion 14 the solar panel support portion 16 and base portion 14 together define a housing interior 36.

As shown in FIGS. 1 and 2 the lighting unit 10 also includes solar panels 37, with two solar panels 37 shown. The solar panels 37 are mounted on the exterior surface 20 of the solar panel support portion 16. It is to be understood that the number of solar panels may be more or less than two, and that solar panels 37 (shown as rectangular shaped solar panels 37a in FIG. 2) may be otherwise shaped, for example shaped as shown in FIG. to be described presently. Adhesives 38, screws or other fasteners are used to secure the solar panels 37 to the solar panel portion 16, and the adhesives 38 are waterproof adhesives in one of the embodiments. The solar panels 37 can be connected or mounted on the solar panel support portion 16 in other ways well know to those having ordinary skill in the art. The solar panel support portion 16 also defines wire openings 39 and solar panel wires 40 (FIG. 1A) extend from the solar panels 37 and through the wire openings 39.

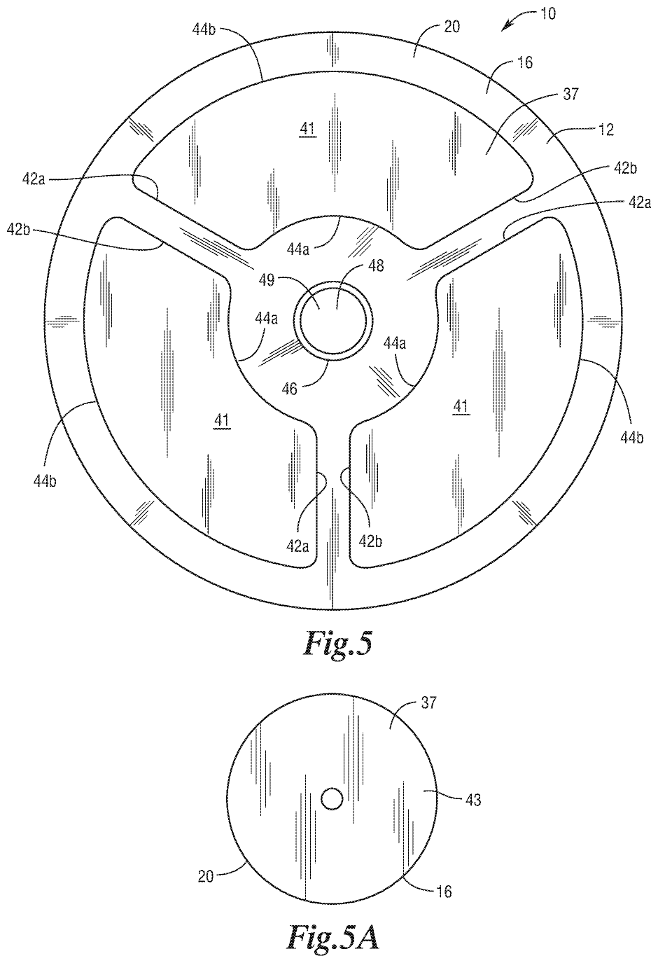

FIG. 5 shows another embodiment illustrating solar panels 37 that are embodied in different shapes. For example, the solar panels 37 shown in FIG. 2 are embodied as rectangular shaped solar panels 37. As shown in FIG. 5, the solar panels 37 are embodied as curved shaped solar panels 41 with each curved shaped solar panel 41 having opposed panel edges 42a, 42b, that may be linear, and each has opposed concave and convex edges 44a, 44b, and there are three solar panels 41. The curved shaped solar panels 41 mimic the circular shape 17 of the solar panel support portion 16. It is to be understood that the shape of the solar panels 37 can be made to have virtually any shape in other embodiments, for example the solar panel 37 may be in the shape of a ring 43 as shown in FIG. 5A. Thus, the shapes of the solar panels 37 can be variously embodied.

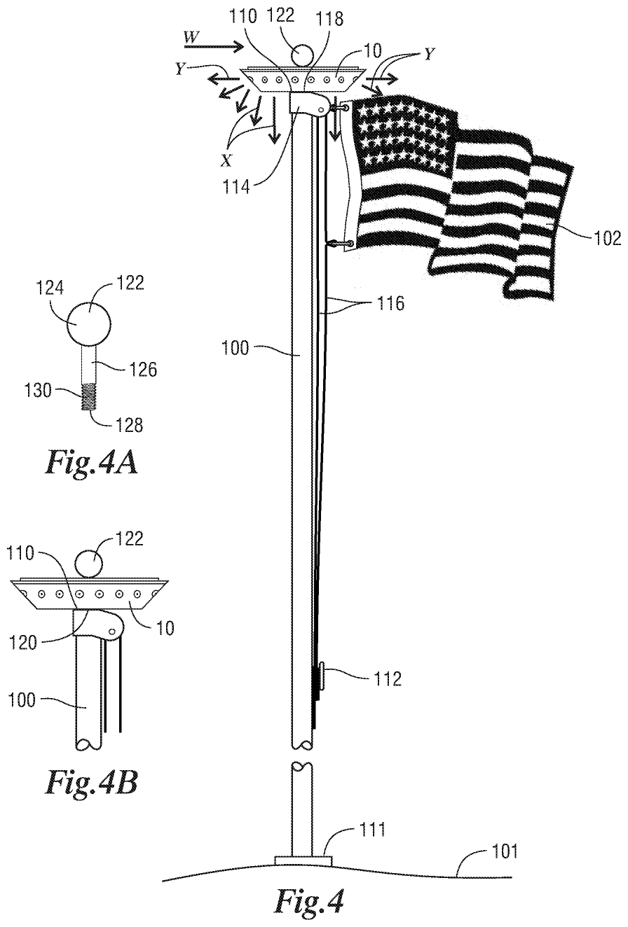

As shown in FIGS. 1-3 and 5, the solar panel support portion 16 has a finial receiving extension 46 that in one embodiment is centrally disposed in the solar panel support portion 16, and in other embodiments the finial receiving extension 46 may be offset relative to the solar panel support portion 16. The finial receiving extension 46 may be made as part of the solar panel support portion 16, or may be embodied as a separate component that is held in place with a friction or pressure fit and with or without adhesives. The finial receiving extension 46 extends to a finial extension end 47. The finial receiving extension 46 defines a finial opening 48 that leads to a finial extension interior 49. As will be described presently, a flagpole finial 122 having a support shaft is provided (FIG. 4A), and the finial opening 48 and the finial extension interior 49 are sized to receive the support shaft 126 therein, with an ornamental portion 124 supported on the support shaft 126. As shown in FIG. 1A, the base wall 22 defines a finial extension opening 51 sized to allow the finial extension end 47 to pass there-through. In one of the embodiments the finial extension end 47 is flush and may be substantially flush with the exterior base wall surface 23b and held in place with a pressure or friction fit with or without adhesives.

As previously described, when the solar panel support portion 16 and the base portion 14 are connected to one another together they define a housing interior 36 as shown in FIG. 1. As shown in FIGS. 1 and 1A, disposed in the housing interior 36 is at least one rechargeable battery 50 and it is pointed out that there may be more than one rechargeable battery 50 as shown. Also disposed in the housing interior 36 are recessed light emitting diodes 56 (hereinafter referred to as recessed LEDs 56), solar light circuitry that includes a light sensor and test button circuitry, and solar panel wires 40 that wired to the solar panels 37 and solar light circuitry 60, and power wires 58 that carry electrical power stored in the rechargeable batteries 50 to the recessed LEDs 56. It is pointed only some of the wiring is not shown in the drawings figures for the sake of clarity, it being understood that there are power wires 58 leading to each of the recessed LEDs 56 so that they can be powered. In another embodiment recessed LEDs 56 are replaced with light bulbs. The solar light circuitry 60 controls the charging and discharging of the rechargeable battery 50 and the turning on and off of the recessed LEDs 56 based on ambient light detection. There is a test button 61 mounted to the base wall 22 that allows the user to test if the recessed LEDs 56 function properly. Thus, when ambient or environmental light falls to a predetermined level as detected by the solar light circuitry 60 the recessed LEDs 56 are powered. In other preferred embodiments the solar light circuitry 60 includes a timer to control the time when the recessed LEDs 56 are powered and not powered. It is pointed out that solar panels, recessed LEDs, rechargeable batteries, and solar panel circuitry used in connection with solar panels and rechargeable batteries and LEDs are well know to those having ordinary skill in the art and is therefore their construction, use and operation are not described in greater detail herein. The rechargeable battery 50 is 3.7V and 3500 mAh to 5400 mAh in one of the embodiments, and the solar panels 37 are 5V and 420 mAh in one of the embodiments. It is to be understood that the voltages and amperages can be different in other embodiments and the lighting unit 10 is not limited to the voltages and amperages described above.

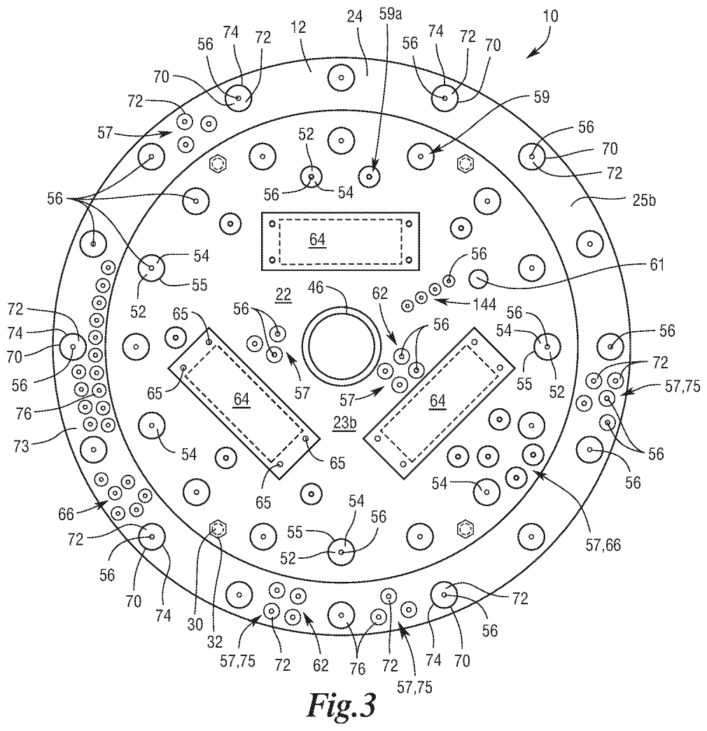

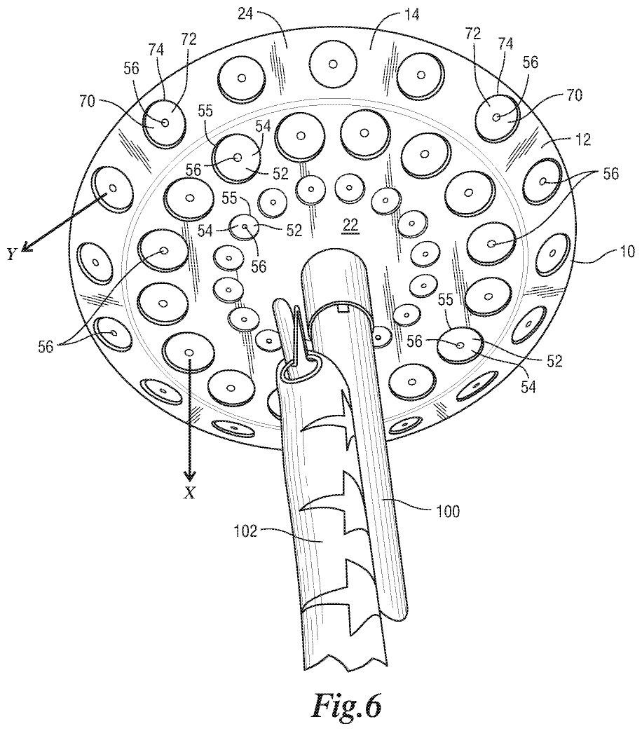

As shown in FIGS. 1, 1A and 3 and the base wall 22 has a plurality of base recesses 52 that are defined by base recess walls 54. The base recess walls 54 extend inwardly from the exterior base wall surface 23b and protrude from the interior base wall surface 23a into the housing interior 36. The base recess walls 54 may be conical shaped or cone shaped in one of the embodiments such that the base recesses 52 are conical shaped or in other embodiments spherical shaped. Each of the base recess walls 54 defines a base recess wall opening 55 (FIG. 1A) with only some show for the sake of clarity. Disposed in each of the base recess wall openings 55 is a recessed LED 56 or other light source, for example a light bulb. The recessed LEDs 56 are held in place with a friction fit or with adhesives or otherwise engage the base recess walls 54. As shown in is a bottom view of the lighting unit 10 the base recess walls 54 are arranged in the shape of a ring 59 of base wall recess walls 54 that extend inwardly into the housing interior 36 such that the recessed LEDs 56 are recessed relative to the exterior base wall surface 23b. FIGS. 3 and 6 show that in one embodiment in addition to the ring 59 base wall recesses 54 there is an inner ring 59a of base wall recesses 54, such that there is double ring or row light emitted from the lighting unit 10. In other embodiments there are addition rings supporting recessed LEDs 56. FIG. 3 shows that base recess walls 54 can also be randomly spaced 66 relative to one another, arranged in groups 57, or can be arranged in patterns 75, for example a rectangular pattern 62. The recessed LEDs 56 may be embodied to emit white light or light of virtually any color. In other preferred embodiments the recessed LEDs 56 can be embodied to flash. It is pointed out that in the drawing figures not all of the recessed LEDs 56, base recess walls 54, base recess wall openings 55 and base recesses 52 have been numbered for the sake of clarity. LEDs and their use and operation are well known to those having ordinary skill in the art and therefore they are not described in greater detail herein. As shown in FIG. 1A, each of the recessed LEDs 56 is wired to the solar light circuitry 60 with LED wires 58 such that each LED 56 is powered by the rechargeable battery 50. Not all the LED wires are shown for the sake of clarity.

As shown in FIG. 3, the base wall 22 also supports at least one access panel 64 with three access panels 64 shown. Access panel screws 65 are used to connect the access panels 64 to the base wall 22 so that the access panels 64 can be installed and removed. The access panels 64 provide access to the housing interior 36 and so that the solar light circuitry 60 and other above-described components disposed in the housing 12 so that they can be accessed, maintained and replaced. It is pointed out that the access panels 64 are not shown in FIG. 1A for the sake of clarity. The user may also gain access to the housing interior 36 by removing the above-described fasteners 32.

As shown in FIGS. 1, 1A and 3, the conical shaped wall 24 also has a plurality of recesses 70 that are defined by recess walls 72. As shown in FIG. 1A, the recess walls 72 extend inwardly from the exterior conical shaped wall surface 25b and protrude from the interior conical shaped wall surfaces 25b and into the housing interior 36. The recess walls 72 may be conical shaped in one of the preferred embodiments such that the recesses 70 have a conical shape. Each of the recess walls 72 defines a recess wall opening 74. Disposed in each of the recess wall openings 74 is a recessed LED 56, or some other light source, for example a light bulb. As shown in FIG. 3 the recess walls 72 are arranged so as to form the shape of a ring 73 that extends around the conical shaped wall 24. In one of the preferred embodiments the recess walls 72 are spaced equal distances from one another. In another embodiment the recess walls 72 are spaced equal distances from one another and each is spaced an equal distance from the conical shaped wall edge 28 and the base wall 22. It is pointed out that in the drawing figures not all the recessed LEDs 56, recesses 70, and the recess walls 72 are numbered for the sake of clarity. In one of the embodiments there are there are sixteen (16) recesses 70 defined in the conical shaped wall 24, but there may be more or less in other preferred embodiments. In another embodiment the recess walls are in the form of a plurality of rings 73 with only a portion of the rings shown in FIG. 3 for the sake of clarity, it being understood that the recess wall can also be randomly spaced 66 relative to one another, arranged in groups 57, or can be arranged in patterns 75, for example a triangular pattern.

The interior conical shaped wall surface 25a makes an angle designated A in FIG. relative to the interior surface 18 of solar panel support portion 16, and angle A is an acute angle. Thus, the conical shaped wall 24 slopes inwardly, that is, the conical shaped wall 24 is tapered as is extends from the solar panel support portion 16 and meets with the base wall 22. In one of the preferred embodiments angle A is forty-five degrees (45°), but could be more or less than 45° in other preferred embodiments. Thus, the light emitted from the recessed LEDs 56 supported by the conical shaped wall 24 is emitted outwardly from the lighting unit 10 and at a 45° angle relative to the light emitted from the recessed LEDs 56 supported by the base wall 22. This providing for full and complete illumination of a flag 102 as will be described presently.

The lighting unit 10 is capable of being used in connection with a flagpole 100 as shown in FIGS. 4, 4A, 4B and 6. FIG. 4 is a perspective view of the above-described lighting unit 10 mounted on a flagpole 100 when the lighting unit 10 is emitting light and illuminating the flag 102 that is supported by a flagpole 100, and the flagpole 100 is supported in the ground 101. FIG. 6 is an enlarged view of the lighting unit 10. The flagpole 100 has a flag end 110 and an opposed ground end 111 for insertion into the ground 101. A rope cleat 112 is mounted on the flagpole 100. A pulley assembly 114 is supported on the flag end 110 of the flagpole 100. A rope 116 is provided and is threaded through by the pulley assembly 114, and the flag 102 is connected to the rope 116 such that pulling the rope 116 raises and lowers the flag 102. Pulley assemblies for use in connection with flagpoles and ropes for raising and lowing flags are well know to those having ordinary skill in the art and are therefore not described greater detail herein. The pulley assembly 114 is supported on the flagpole 100 with a friction fit, or it may be held in place with a fastener that extends through the pulley assembly 114 and flagpole 100. The pulley assembly 114 has a flagpole finial opening 118 that has an internal pulley thread 120. As shown in FIGS. 4-4BA flagpole finial 122 is provided that has a ball portion 124. The flagpole finial 122 has a support shaft 126, with the support shaft 126 extending from the ball portion 124. It is pointed out that the ball portion 124 can be differently shaped in other preferred embodiments, for example it may have the shape of an eagle. Thus, as used herein, the term ball portion 124 is not limited to a ball or sphere shape, but rather, it includes all shapes and designs used for flagpole finials such as eagles, logos, and the like. As shown in FIG. 4A, the support shaft 126 has distal end 128 and an external shaft thread 130 extends from the distal end 128 and along the support shaft 126. The external shaft thread 130 is sized such that it is capable of being threaded to the internal pulley thread 120, such that when support shaft 126 is threaded to the internal pulley thread 120 the flagpole finial 122 extends from the flag end of 110 of the flagpole 100, for example it extends upwardly. Flagpoles, finials and mounting finials on flagpoles, and pulleys for use with flagpoles having finials are all well known to those having ordinary skill in the and are therefore not described in greater detail herein.

The lighting unit 10 is supported and disposed above the flag 102. In particular, the finial opening 48 defined in finial receiving extension 46 of the lighting unit 10 is aligned with the flagpole finial opening 118. The support shaft 126 is then moved through the finial opening 48. The support shaft 126 extends through finial opening 48 defined in the finial receiving extension 46, and its external shaft thread 130 is threaded to the internal pulley thread 120, such that the lighting unit 10 is positioned between the ball portion 124 of the flagpole finial 122 and the pulley assembly 114, while at the same time is securely supported by and secured to the flagpole 100. This allows the lighting unit 10 to be readily installed and removed by the owner of the flagpole 100.

The lighting unit 10 provides for thorough and complete illumination of the flag because light is emitted from the recessed LEDs 56 from the base portion 14 and from the conical shaped wall 24. Some light will scatter to some extent after passing beyond the base wall 22 in the directions as shown in FIGS. 4 and 6. As shown, some of the light is cast vertically downward toward the ground 101 and some the light is cast at an angle downward in the direction of the ground 101 by the light that is emitted by the recessed LEDs 56 supported by the base wall 22 (as indicated by the arrows designated X in FIG. 4). At the same time light emitted from the recessed LEDs 56 supported by the conical shaped wall 24 (as indicated by the arrows designated Y in FIG. 4) is at about a forty-five degrees (45°) angle relative to the flagpole 100 and will scatter in that direction. It is pointed out that the base recess walls 54 and the recess walls 72 focus or direct the light emitted from the recessed LEDs 56. Thus the recessed LEDs 56 supported by the base wall 22 illuminate the flag 102 when there is no wind and the flag 102 is simple hanging from the flagpole 100. When there is a breeze or wind and the flag 102 begins to wave in the wind (designated W in FIG. 4) the flag 102 is blow out and away from the flagpole 100. The recessed LEDs 56 that are supported on the conical shaped wall 24 cast or emit light on the waving flag 102 (as indicated by the arrows designated Y). At the same time, the recessed LEDs 56 supported by the base wall 22 illuminate portions of the flag 102. Thus, the flag 102 is fully illuminated by the lighting unit 10 throughout the night, regardless of whether or not there is or is not a breeze or wind. The rechargeable batteries 50 are capable of illuminating the flag 102 for twelve (12) or more hours in one embodiment.

It is pointed out that the lighting unit 10 shown in FIGS. 4 and 6 can also be embodied to have additional lighting as described above and shown in FIGS. 1A and 3. In other words, the embodiments of the lighting unit 10 shown in FIGS. 1A and 3 can be mounted on the flagpole 100 as described above to provide for additional lighting.

In another preferred embodiments the lighting unit 10 can be differently shaped. That is, the solar panel support portion 16 and base wall 22 can be made to have virtually any desired geometrical shape. For example they can be rectangular shaped, oval shaped, and polygonal shaped. The conical shaped wall would be tapered and would have a geometry or shape that mimics the geometry or shape of the solar panel support portion and base wall, and in another embodiment the conical wall and would have the same geometry as the base wall and the solar panel support portion. All of these embodiments are within the scope of the lighting unit 10.

In another preferred embodiment the lighting unit 10 can be mounted on, for example a post (not shown) and secured in place with a bolt that extends through the finial receiving extension 46.

### Surface Lights

In another embodiment and as shown in FIGS. 1, 6A and 6B and 8, the lighting unit 10 has, in one embodiment, at least one surface mounted LED 140 that extends from the exterior conical wall surface 25b and at least one surface mounted LED 140 that extends from the exterior base wall surface 23b. This means the surface mounted LEDs 140 are not positioned in the base recesses 52 defined in the base wall 22 and are not positioned in the recesses 70 defined in the conical shaped wall 24. Rather, the surface mounted LEDs 140 extend from the exterior base wall surface 23b and exterior conical wall surface 25b.

In one embodiment surface mounted LEDs 140 that extends from the exterior conical wall surface 25b and extend from the exterior base wall surface 23b may be used alone (FIG. 6B), or together, or they may be used combination with the above described embodiments wherein there are base recesses 52 and the base recess walls that support recessed LEDs 56 and recesses 70 and the recess walls 72 that support recessed LEDs 56 (FIG. 6A). The surface mounted LEDs 140 are powered in the same manner as described above with solar panels 37. The surface mounted LEDs 140 illuminate the flag 102. The surface mounted LEDs 140 can be arranged in any shape or configuration, for example and as shown in FIGS. 6A and 6B they can be arranged randomly 140, in a pattern 142, linearly 144, in circles 146 and in rectangles 148 or any other desired shape or pattern.

Thus, the base wall 22 and conical shaped wall 24 can be embodied with surface mounted LEDs 140 that extend from the exterior conical wall surface 25b and at least one surface mounted LED 140 that extends from the exterior base wall surface 23b in virtually any desired shape or pattern.

### Other Shapes

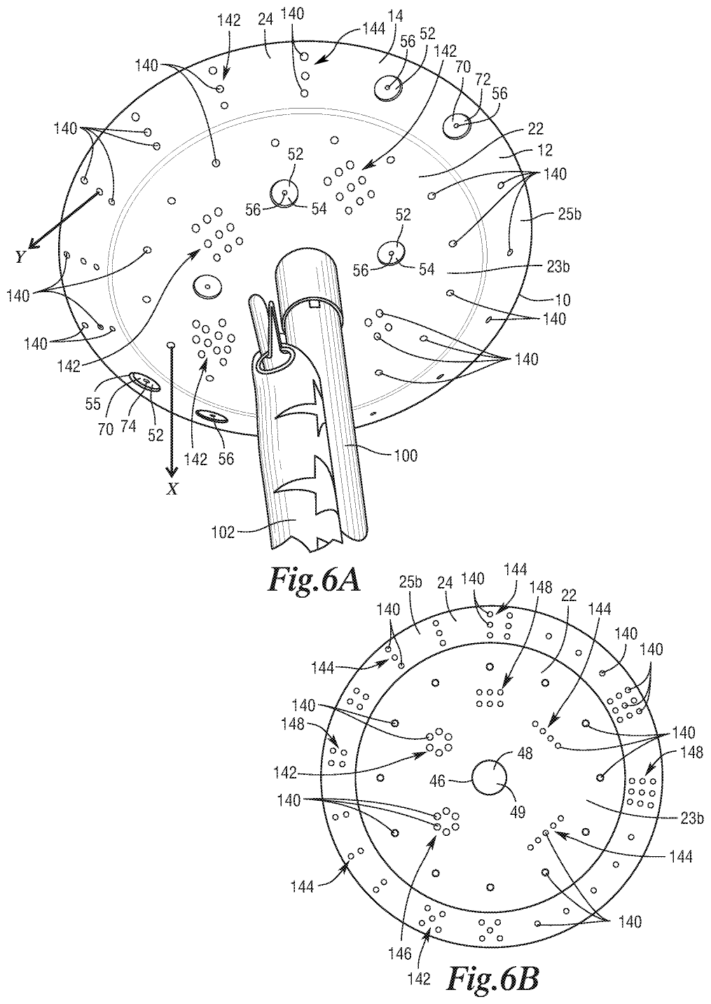

As shown in FIG. 7, in another embodiment the lighting unit 10 the housing has the base wall 22 and solar panel support portion 16, but the surrounding wall 21a is embodied as a cylindrical shaped wall 160 that extends from the base wall 22. The cylindrical shaped wall 160 has a cylindrical shaped wall edge 164 that abuts the solar panel support portion 16 as shown. The cylindrical shaped wall has interior and exterior cylindrical wall surfaces 162a, 162b. Together, the base wall 22, the solar panel support portion 16 and the cylindrical wall 160 define the above described housing interior 36. In one embodiment the exterior cylindrical shaped wall surface 162b is uniform and smooth and does not have any openings or recesses.

In one embodiment the cylindrical shaped wall 160 has recess walls 72 that support recessed LEDs 56 in the manner previously described, that is, the difference between the conical shaped wall 24 and the cylindrical shaped wall 160 is the shape of each is different, with the recessed LEDs 56, the solar panels 37, the base recess walls 54 and wall openings 55, the solar panel support portion 16, the solar panel wires 40 and wiring, and the shapes of the solar panels 37, and the recess walls 72 being the same as previously described.

In another embodiment the cylindrical shaped wall 160 supports at least one surface mounted LED 140 and in other embodiments supports a plurality of surface mounted LEDs 140. The surface mounted LEDs 140 can be in arranged in virtually any shape or pattern, for example they can be arranged in a pattern 142, linearly 144, in circles 146 and in rectangles 148 or any other desired shape or pattern. In addition, the base wall 22 and the solar panel support portion 16 can have surface mounted LEDs 140 as described above in connection with other embodiments described herein.

The base wall 22 and the cylindrical shaped wall 160 may be formed as a one-piece body 26 and are plastic in one embodiment, but may be may be made of metal or other materials in other embodiments, or they may be made separately and held together with, for example adhesives in other embodiments. It is pointed out that the cylindrical shaped wall 160 has a wall edge 164 that abuts against the solar panel support portion 16 such that the solar panel support portion 16 is supported on the cylindrical shaped wall 160. The cylindrical shaped wall 160 is perpendicular to the base wall 22 and the solar panel support portion 16.

### Top Mounted Lights

The lighting unit 10 provides a way to cast light or illuminate the flagpole finial regardless of how the flagpole finial 122 is embodied, for example, as a ball portion described above, or as an eagle finial or rooster-shaped finial (not shown). The finial can be illuminated regardless its shape, form, or configuration.

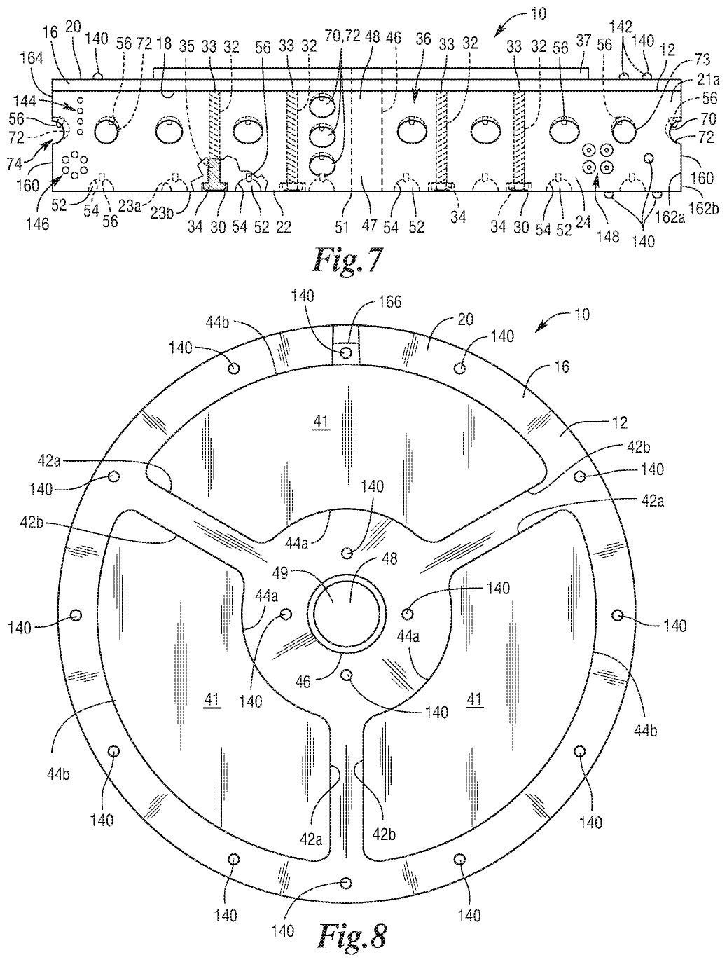

As shown in FIGS. 7 and 8, the solar panel support portion 16 supports at least one surface mounted LED 140. The surface mounted LED 140 is mounted so as to extend above the exterior surface 20 of the solar panel support portion 16 and is supported by the solar panel support portion 16. The surface mounted LEDs 140 may be spaced one hundred twenty degrees (120°) from one another. In other embodiments there can be a plurality of surface mounted LEDs 140 that are supported on the solar support portion 16 and arranged in the shape of a circle or randomly. The surface mounted LEDs 140 are mounted so as to extend above the exterior surface 20 of the solar panel support portion 16. The surface mounted LEDs 140 may be held in place with a friction fit, pressure fit or with adhesives, for example waterproof adhesives.

In other embodiments, there can be LED mounts 166 that extend from the solar panel support portion 16 and the LED mounts support the surface mounted LEDs 140.

The surface mounted LEDs 140 supported by the solar panel support portion are wired to and powered by the rechargeable battery 50 in the manner previously described above for powering recessed and surface mounted LEDs 56, 140.

It is pointed out that in any of the embodiments described herein the solar panel support portion 16 can support at least one surface mounted LED 140.

### Inverted Conical Shape

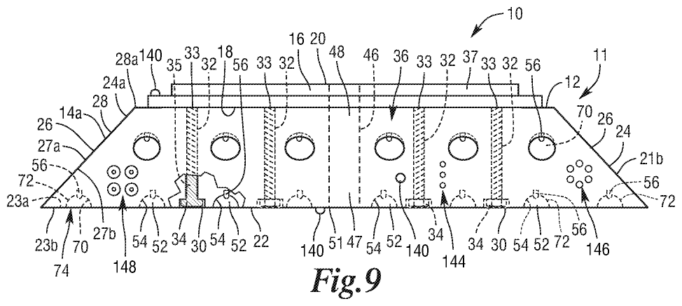

In another embodiment shown in FIG. 9, the lighting unit 10 has a surrounding wall 21b that is embodied as an inverted conical shaped wall 24a (relative to the previously described conical shaped wall 24) that extends from the base wall 22 to form a base portion 14a. The solar panel support portion 16 is supported on the inverted conical shaped wall 24b. The inverted conical shaped wall 24a has interior and exterior internal inverted conical wall surfaces 27a, 27b. The inverted conical shaped wall 24a extends from the base wall 22. The inverted conical shaped wall 24a flares outwardly as it extends from the solar panel support portion 16 to the base wall 22 as shown, such that the base wall 22 has a greater diameter than the diameter of the solar panel support portion 16. The inverted conical shaped wall 24a has recess walls 72 that support recessed LEDs 56 in the manner previously described. One difference between the conical shaped wall 24 and inverted conical shaped wall 24a is the angle each makes as it extends from the solar panel support portion 16 to the base wall 22. It is to be understood that the recessed LEDs 56, the solar panels 37, the base recess walls 54 and wall openings 55, the solar panel support portion 16, the solar panel wires 40 and wiring, and the shapes of the solar panels 37, recess walls 72 are the same as previously described.

In addition, the in one embodiment the inverted conical shaped wall 24a has at least one surface mounted LED 140 and in other embodiments has a plurality of surface mounted LEDs 140. The surface mounted LEDs 140 can be in arranged in virtually any shape or pattern, for example they can be arranged in a pattern 142, linearly 144, in circles 146 and in rectangles 148 or any other desired shape or pattern. In addition, the base wall 22 and the solar panel support portion 16 can have surface mounted LEDs 140.

The base wall 22 and the inverted conical shaped wall 24a may be formed as a one-piece body 26 and are plastic in one embodiment, but may be may be made of metal or other materials in other embodiments, or they may be made separately and held together with, for example adhesives in other embodiments.

It is pointed out that in other embodiments the solar panel support portion 16 may or may not have surface mounted LEDs 140.

In other embodiments the conical shaped wall 24 and the inverted conical shaped wall 24a may or may not have surface mounted lights 140.

In other embodiments the cylindrical shaped wall 160 may or may not have surface mounted LES 140.

In other embodiments the base wall may or may not have surface mounted LEDs 140.

It will be appreciated by those skilled in the art that while a lighting unit 10 has been described in connection with the embodiments and examples thereof, the lighting unit 10 is not necessarily so limited and that other examples, uses, modifications, and departures from the embodiments, examples, and uses may be made without departing from the lighting unit 10. All these embodiments are intended to be within the scope and spirit of the appended claims.

What is claimed:

1. A lighting unit comprising:
a base wall having interior and exterior base wall surfaces;
a solar panel support portion having opposed interior and exterior solar panel surfaces and a solar panel mounted on the exterior solar panel surface;
a conical shaped wall having interior and exterior conical wall surfaces and the conical shaped wall extends from the base wall to the solar panel support wall, and a diameter of the conical shaped wall increases as the conical shaped wall extends from the base wall to the solar panel support portion, and the solar panel support portion is mounted on the conical shaped wall;
a base recess wall formed in the base wall that defines a base recess wall opening and a recessed light emitting diode supported in the base recess wall;
a recess wall formed in the conical shaped wall the recess wall that defines a recess wall opening and a recessed light emitting diode supported in the recess wall; and,
a rechargeable battery wired to the solar panel and the recessed light emitting diodes and for powering the recessed light emitting diodes.

2. The lighting unit according to claim 1 wherein the truncated conical wall has a plurality of recess walls that support light emitting diodes and the plurality of recess walls can be arranged in any of the following configurations including: a ring arranged circumferentially around the truncated wall, double rings arranged circumferentially around the truncated wall, triple rings arranged circumferentially around the truncated wall, linearly from the base wall to the solar panel support portion, in the form of patterns, and randomly.

3. The lighting unit according to claim 1 wherein the base wall has a plurality of base recess walls that support light emitting diodes and the plurality of base recess walls can be arranged in any of the following configurations including: a ring arranged circumferentially around the base wall, double rings arranged circumferentially around the base wall, triple rings arranged circumferentially around the base wall, linearly, in the form of patterns, and randomly.

4. The lighting unit according to claim 1 wherein the solar panel support portion supports at lease one surface mounted light emitting diode that is wired to the rechargeable battery.

5. The lighting unit according to claim 1 wherein the truncated conical wall supports at least one surface mounted light emitting diode that is wired to the rechargeable battery.

6. The lighting unit according to claim 1 wherein the base wall supports at least one surface mounted light emitting diode that is wired to the rechargeable battery.

7. The lighting unit according to claim 2 wherein the truncated conical wall supports at least one surface mounted light emitting diode that is wired to the rechargeable battery.

8. The lighting unit according to claim 3 wherein the base wall supports at least one surface mounted light emitting diode that is wired to the rechargeable battery.

9. A lighting unit comprising:
a base wall having interior and exterior base wall surfaces;
a solar panel support portion having interior and exterior solar panel surfaces and a solar panel mounted on the exterior solar panel surface;
a cylindrical shaped wall having interior and exterior cylindrical wall surfaces and the cylindrical shaped wall extends from the base wall to the solar panel support wall, and the solar panel support portion is mounted on the cylindrical shaped wall;
a base recess wall formed in the base wall that defines a base recess wall opening and a recessed light emitting diode supported in the base recess wall; and,
a rechargeable battery wired to the solar panel and the recessed light emitting diode and for powering the recessed light emitting diode.

10. The lighting unit according to claim 9 wherein the solar panel support portion supports at lease one surface mounted light emitting diode that is wired to the rechargeable battery.

11. The lighting unit according to claim 9 wherein the base wall has a plurality of base recess walls that support light emitting diodes and the plurality of base recess walls can be arranged in any of the following configurations including: a ring arranged circumferentially around the base wall, double rings arranged circumferentially around the base wall, triple rings arranged circumferentially around the base wall, linearly, in the form of patterns, and randomly.

12. The lighting unit according to claim 9 wherein the base wall supports at least surface mounted light emitting diode that is wired to the rechargeable battery.

13. The lighting unit according to claim 9 wherein the cylindrical wall supports at least one surface mounted light emitting diode that is wired to the rechargeable battery.

14. A lighting unit comprising:
a base wall having interior and exterior base wall surfaces;
a solar panel support portion having opposed interior and exterior solar panel surfaces and a solar panel mounted on the exterior solar panel surface;
an enclosing wall that extends from the base wall to the solar panel support portion and supports the solar panel support portion,
a base recess wall formed in the base wall that defines a base recess wall opening and a recessed light emitting diode supported in the base recess wall;
a rechargeable battery wired to the solar panel and the recessed light emitting diodes and for powering the recessed light emitting diodes.

15. The lighting unit according to claim 14 wherein the base wall has a plurality of base recess walls that support light emitting diodes and the plurality of base recess walls can be arranged in any of the following configurations including: a ring arranged circumferentially around the base wall, double rings arranged circumferentially around the base wall, triple rings arranged circumferentially around the base wall, linearly, in the form of patterns, and randomly.

16. The lighting unit according to claim 15 wherein the enclosing wall has a truncated conical shape.

17. The lighting unit according to claim 15 wherein the enclosing wall has a cylindrical shape.

18. The lighting unit according to claim 15 wherein the enclosing wall has an inverted conical shape.

19. The lighting unit according to claim 14 further including a surface mounted light emitting diode and the light emitting diode can be mounted on at least one of the following: the conical wall, the cylindrical wall and the inverted conical wall that is wired to the rechargeable battery
